(19) United States
(12) Patent Application Publication
(10) Pub. No.: US 2019/0148548 A1
(43) Pub. Date: May 16, 2019

(54) Dual Gate Dielectric Transistor

(71) Applicant: Taiwan Semiconductor Manufacturing Co., Ltd., Hsin-Chu (TW)

(72) Inventor: Ching-Hung Kao, Tainan City (TW)

(21) Appl. No.: 16/102,126

(22) Filed: Aug. 13, 2018

Related U.S. Application Data
(60) Provisional application No. 62/587,221, filed on Nov. 16, 2017.

(51) Int. Cl. H01L 29/78; H01L 29/06; H01L 29/08; H01L 29/49; H01L 29/45; H01L 29/417; H01L 29/66; H01L 29/423

(52) U.S. Cl. CPC H01L 29/7835; H01L 29/0653; H01L 29/0847; H01L 29/4983; H01L 29/45; H01L 29/7851; H01L 21/02532; H01L 29/66795; H01L 29/7831; H01L 29/66484; H01L 29/42364; H01L 29/66659; H01L 29/665; H01L 29/41791

(57) ABSTRACT

The semiconductor structure includes a semiconductor substrate; a first active region and a second active region on the semiconductor substrate and separated by an isolation feature; and a field-effect transistor formed on the semiconductor substrate. The field-effect transistor further includes a gate stack disposed on the semiconductor substrate and extending from the first active region to the second active region; and a source and a drain formed on the first active region and interposed by the gate stack. The semiconductor structure further includes a doped feature formed on the second active region and configured as a gate contact to the field-effect transistor.

### PRIORITY

This application claims priority to U.S. Prov. Pat. App. Ser. No. 62/587,221, filed Nov. 16, 2017, herein incorporated by reference in its entirety.

### BACKGROUND

An integrated circuit is formed on a semiconductor substrate and includes various devices, such as transistors, diodes, and/or resistors, configured and connected together to a functional circuit. The integrated circuit further includes core devices and I/O devices. The I/O devices usually experience high voltages during field application and are designed with robust structure to survive high-voltage applications. In the existing high-voltage transistors or I/O transistors, the gate structure is designed with a gate dielectric layer of a greater thickness. However, the thicker gate dielectric layer degrades the quality of the interface state, causing more noises, such as flicker noise and random telegraph signal (RTS) noise, to the devices during the field application. Thinning down the gate dielectric thickness will degrade the high voltage performance. It is therefore desired to have a new device structure and the method making the same for high voltage applications and other applications to address the above concerns.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A is a top view of a semiconductor device structure constructed according to various aspects of the present disclosure in one embodiment.

FIGS. 1B, 1C and 1D are sectional views of the semiconductor structure of FIG. 1A along the dashed lines AA′, BB′ and CC′ respectively, in accordance with some embodiments.

FIG. 2 is a schematic view of a transistor gate in the semiconductor structure of FIG. 1A, in accordance with some embodiments.

FIG. 3 is a flowchart of a method making the semiconductor structure, in accordance with some embodiments.

FIG. 4A is a top view of a semiconductor device structure constructed according to various aspects of the present disclosure in one embodiment.

FIGS. 4B, 4C and 4D are sectional views of the semiconductor structure of FIG. 4A along the dashed lines AA′, BB′ and CC′ respectively, at a fabrication stage, in accordance with some embodiments.

FIG. 5A is a top view of a semiconductor device structure constructed according to various aspects of the present disclosure in one embodiment.

FIGS. 5B, 5C and 5D are sectional views of the semiconductor structure of FIG. 5A along the dashed lines AA′, BB′ and CC′ respectively, at a fabrication stage, in accordance with some embodiments.

FIG. 6A is a top view of a semiconductor device structure constructed according to various aspects of the present disclosure in one embodiment.

FIGS. 6B, 6C and 6D are sectional views of the semiconductor structure of FIG. 6A along the dashed lines AA′, BB′ and CC′ respectively, at a fabrication stage, in accordance with some embodiments.

FIG. 7A is a top view of a semiconductor device structure constructed according to various aspects of the present disclosure in one embodiment.

FIGS. 7B, 7C and 7D are sectional views of the semiconductor structure of FIG. 7A along the dashed lines AA′, BB′ and CC′ respectively, at a fabrication stage, in accordance with some embodiments.

FIG. 8 is a sectional view of the semiconductor structure at a fabrication stage, in accordance with some embodiments.

FIG. 9 is a sectional view of the semiconductor structure of FIG. 1 with fin active regions, constructed in accordance with some embodiments.

FIG. 10 is a top view of a semiconductor device structure constructed according to various aspects of the present disclosure in other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. It is to be understood that the following disclosure provides many different embodiments, or examples, for implementing different features of various embodiments.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

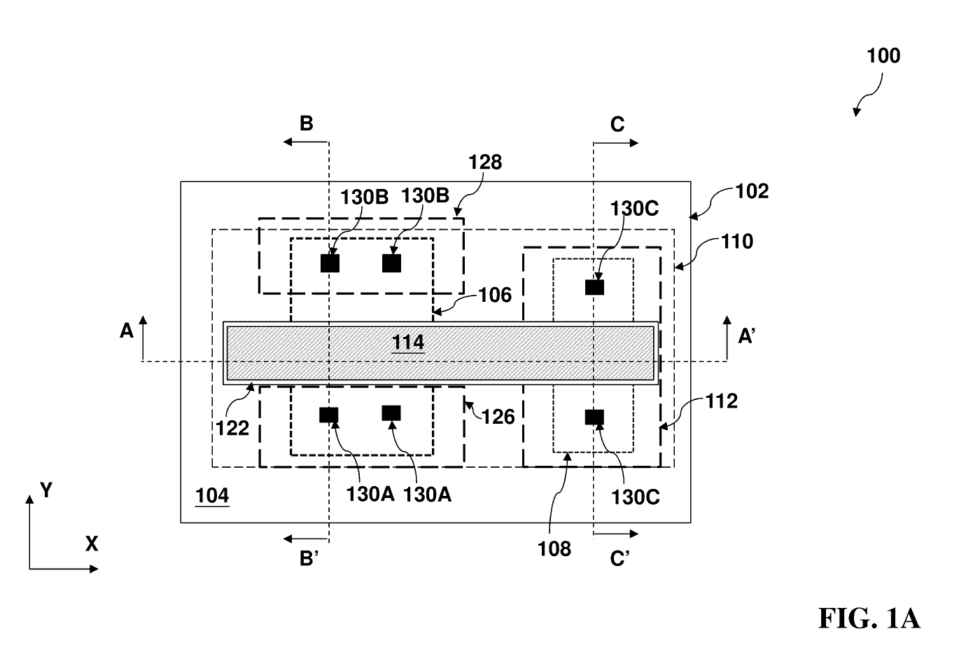

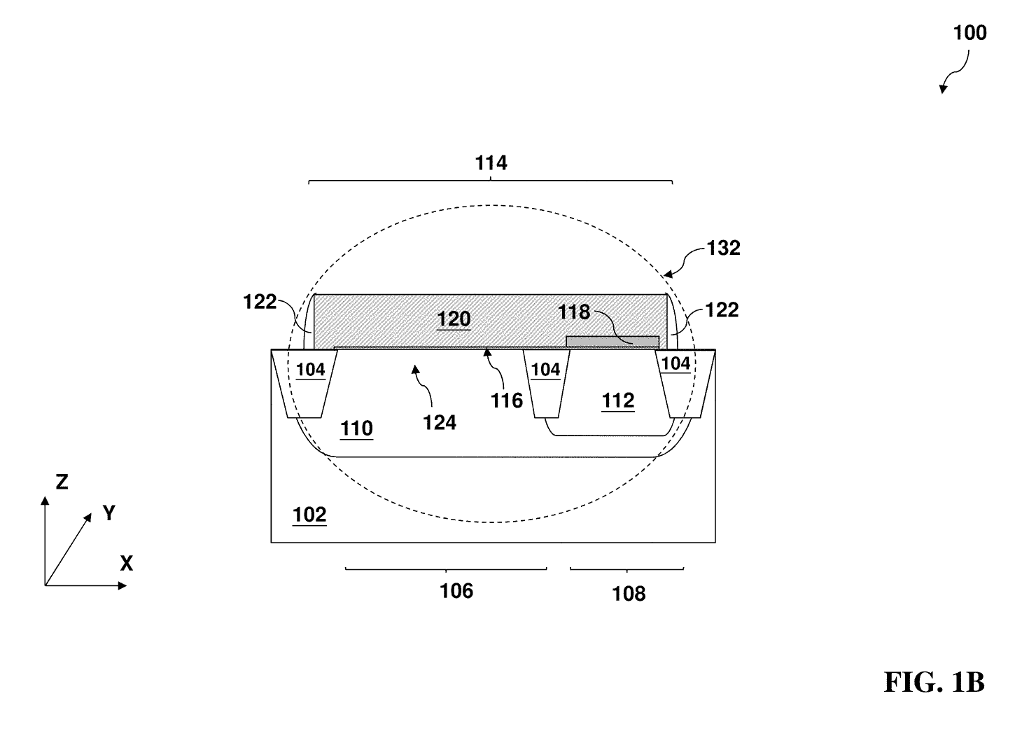

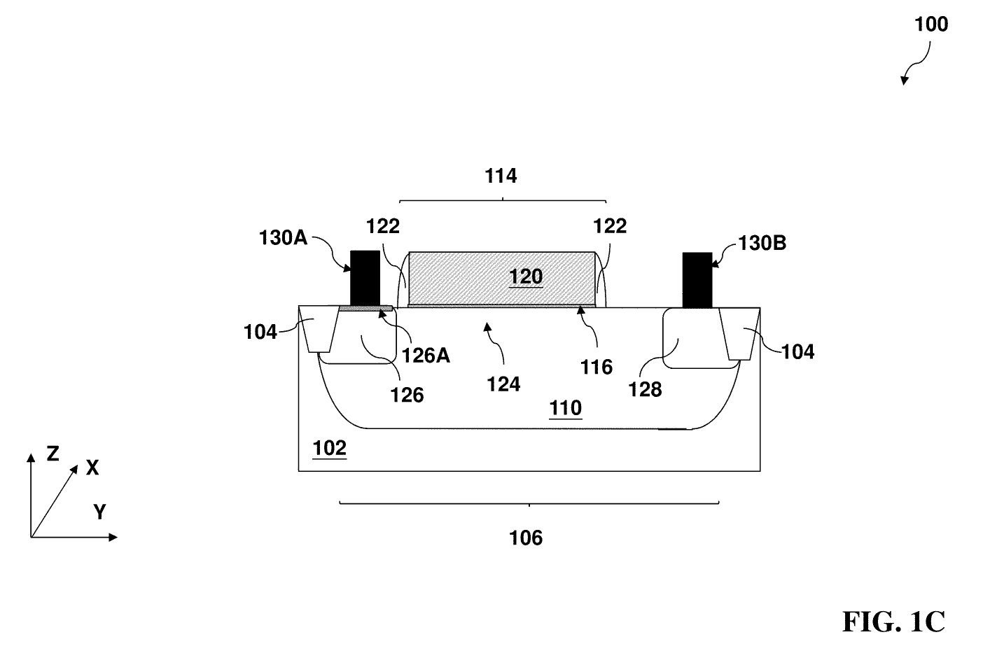

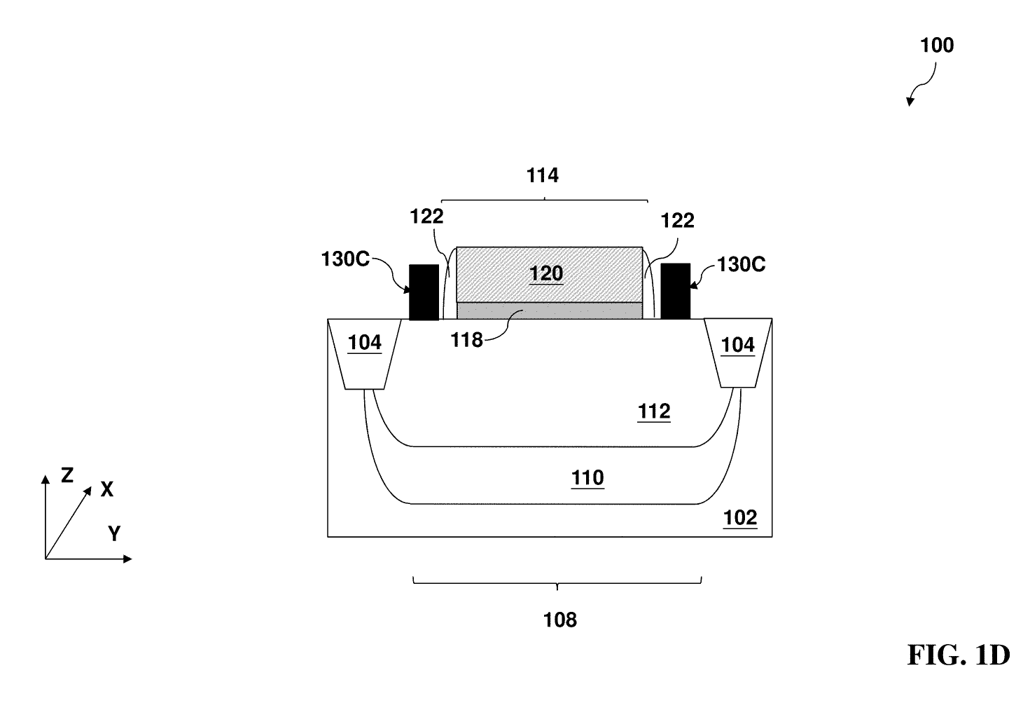

FIG. 1A is a top view of a semiconductor structure (or a work piece) 100 constructed according to various aspects of the present disclosure in one embodiment. FIGS. 1B, 1C and 1D are sectional views of the semiconductor structure 100 along the dashed lines AA′, BB′ and CC′ respectively, in accordance with some embodiments. The semiconductor structure 100 and the method making the same are collectively described with reference to FIGS. 1A through 1D. In some embodiments, the semiconductor structure 100 is formed on fin active regions and includes fin field-effect transistors (FinFETs). In some embodiments, the semiconductor structure 100 is formed on flat fin active regions and includes plain field-effect transistors (FETs). The semiconductor structure 100 includes a dual gate dielectric FET that may be n-type, p-type, a complementary MOSFET having both an n-type FET (nFET) and a p-type FET (pFET). As an example for illustration only but not limiting, the dual gate dielectric FET is an nFET.

The semiconductor structure 100 includes a substrate 102. The substrate 102 includes a bulk silicon substrate. Alternatively, the substrate 102 may include an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. Possible substrate 102 also includes a silicon-on-insulator (SOI) substrate. SOI substrates are fabricated using separation by implantation of oxygen (SIMOX), wafer bonding, and/or other suitable methods.

The substrate 102 also includes various isolation features, such as isolation features 104 formed on the substrate 102 and defining various active regions, such as a first active region 106 and a second active region 108, on the substrate 102. The isolation feature 104 utilizes isolation technology, such as local oxidation of silicon (LOCOS) and/or shallow trench isolation (STI), to define and electrically isolate the various regions. The isolation feature 104 includes silicon oxide, silicon nitride, silicon oxynitride, other suitable dielectric materials, or combinations thereof. The isolation feature 104 is formed by any suitable process. As one example, forming STI features includes using a lithography process to expose a portion of the substrate, etching a trench in the exposed portion of the substrate (for example, by using a dry etching and/or wet etching), filling the trench (for example, by using a chemical vapor deposition process) with one or more dielectric materials, and planarizing the substrate and removing excessive portions of the dielectric material(s) by a polishing process, such as chemical mechanical polishing (CMP). In some examples, the filled trench may have a multi-layer structure, such as a thermal oxide liner layer filled with silicon nitride or silicon oxide.

The active regions (such as 106 and 108) are those regions with semiconductor surface wherein various doped features are formed and configured to one or more device, such as a diode, a transistor, and/or other suitable devices. The active regions may include a semiconductor material similar to that (such as silicon) of the bulk semiconductor material of the substrate 102 or different semiconductor material, such as silicon germanium (SiGe), silicon carbide (SiC), or multiple semiconductor material layers (such as alternatively silicon and silicon germanium layers) formed on the substrate 102 by epitaxial growth, for performance enhancement, such as strain effect to increase carrier mobility. The first active region 106 and the second active region 108 are spaced away from each other along the X direction and separated by the isolation feature 104. The X direction is orthogonal to the Y direction, defining the top surface of the substrate 102. The top surface has a normal direction along the Z direction, which is orthogonal to both X and Y directions.

In some embodiments, the active regions 106 and 108 are three dimensional, such as fin active regions extruded above the substrate 102. The fin active regions may be formed by selective etching to recess the isolation features 104, or selective epitaxial growth to grow active regions with a semiconductor same or different from that of the substrate 102, or a combination thereof.

The semiconductor substrate 102 further includes various doped features, such as n-type doped wells, p-type doped wells, source and drain, other doped features, or a combination thereof configured to form various devices or components of the devices. In the present embodiment, the semiconductor substrate 102 includes a doped well 110 of a first-type. In the present example, the doped well 110 is doped with a p-type dopant (therefore referred to as p-well). The doped well 110 is extended from the first active region 106 to the second active region 108. In the present embodiment, the doped well 110 encloses the first active region 106 and the second active region 108 in the top view, as illustrated in FIG. 1A. The dopant (such as boron) in the doped well 110 may be introduced to the substrate 102 by ion implantation or other suitable technique. The doped well 110 may be formed by a procedure that includes forming a patterned mask with an opening on the substrate 102 wherein the opening defines the region for the doped well 110; and performing an ion implantation to introduce the dopant into the substrate 102 using the patterned mask as an implantation mask. The patterned mask may be a patterned resist layer formed by lithography or a pattern hard mask formed by lithography process and etching.

The semiconductor substrate 102 also includes a doped feature 112 of a second type dopant, which is opposite to the first type dopant. In the present example, the doped feature 112 is an n-type doped and has an n-type dopant, such as phosphorus. The doped feature 112 is heavily doped (referred to as the doped feature of N⁺ in the present example) for increased conductivity. The doped feature 112 is portion of the dual gate dielectric FET and is configured to function as a contact to a gate stack 114. This will be further described in details at later stage.

The doped feature 112 is formed in the second active region 108 of the substrate 102. Particularly, the doped feature 112 is continuously extended on the second active region 108 along the Y direction from a first region on one side of the gate stack 114 to a second region underlying the gate stack 114. In some embodiments, the doped feature 112 is further extended continuously along the Y direction from a second region underlying the gate stack 114 to a third region on an opposite side of the gate stack 114. In the present example, the doped feature 112 is enclosed within the doped well 110, as illustrated in FIGS. 1A and 1D. In some embodiments, the doped feature 112 further extends to the isolation feature 104 and encloses the second active region 108 in the top view, as illustrated in FIG. 1A. The dopant (such as phosphorous) in the doped feature 112 may be introduced to the substrate 102 by ion implantation or other suitable technique similar to that of the doped well 110. For example, the doped feature 112 may be formed by a procedure that includes forming a patterned mask with an opening on the substrate 102 wherein the opening defines the region for the doped feature 112; and performing an ion implantation to introduce the dopant into the substrate 102 using the patterned mask as an implantation mask.

The semiconductor structure 100 further includes a gate stack 114 having an elongated shape oriented in X direction. The gate stack 114 continuously extends from the first active region 106 to the second active region 108. Furthermore, the gate stack 114 extends beyond the first and second active regions to the isolation features 104. The gate stack 114 includes dual gate dielectric layers: a first gate dielectric layer 116 on the first active region 106 and a second gate dielectric layer 118 on the second active region 108. The dual gate dielectric layers have different thicknesses. Particularly, the first gate dielectric layer 116 has a first thickness and the second gate dielectric layer 118 has a second thickness greater than the first thickness. The first and second gate dielectric layers can separately formed by a suitable procedure with independent thickness, thus can be separately tuned for better device performance. Each of the gate dielectric layers (116 and 118) includes a dielectric material, such as silicon oxide. In other embodiments, each of the gate dielectric layers alternatively or additionally includes other suitable dielectric materials for circuit performance and manufacturing integration. For example, each gate dielectric layers (116 and 118) includes a high k dielectric material layer, such as metal oxide, metal nitride or metal oxynitride. In various examples, the high k dielectric material layer includes metal oxide: ZrO2, Al2O3, and HfO2, formed by a suitable method, such as metal organic chemical vapor deposition (MOCVD), physical vapor deposition (PVD), atomic layer deposition (ALD), or molecular beam epitaxy (MBE). The gate dielectric layers (116 and 118) may further include an interfacial layer interposed between the semiconductor substrate 102 and the high k dielectric material. In some embodiments, the interfacial layer includes silicon oxide formed by ALD, thermal oxidation or ultraviolet-Ozone Oxidation.

The gate stack 114 further includes a gate electrode 120 disposed on the first and second gate dielectric layers. The gate electrode 120 includes metal, such as aluminum, copper, tungsten, metal silicide, metal alloy, doped poly-silicon, other proper conductive material or a combination thereof. The gate electrode 120 may include multiple conductive films designed such as a capping layer, a work function metal layer, a blocking layer and a filling metal layer (such as aluminum or tungsten). The multiple conductive films are designed for work function matching to nFET (or pFET). In some embodiments, the gate electrode 120 for nFET includes a work function metal with a composition designed with a work function equal 4.2 eV or less. In other cases the gate electrode for pFET includes a work function metal with a composition designed with a work function equal 5.2 eV or greater. For examples, the work function metal layer for nFET includes tantalum, titanium aluminum, titanium aluminum nitride or a combination thereof. In other examples, the work function metal layer for pFET includes titanium nitride, tantalum nitride or a combination thereof.

The gate stack 114 is formed by various deposition techniques and a proper procedure, such as a gate-last process, wherein a dummy gate is first formed, and then is replaced by a metal gate after the formation the source and drain. Alternatively, the gate stack 114 is formed by high-k-last process, wherein the both gate dielectric material layer and the gate electrode are replaced by a high-k dielectric material and metal, respectively, after the formation of the source and drain. One gate stack 114 and the method making the same are further described in accordance with some embodiments. In one example, the first and second gate dielectric layers are separately formed by a procedure including deposition and patterning. In another example, the second gate dielectric layer is deposited and patterned (that includes lithography process and etching) such that the second gate dielectric layer is on the second active region 108 but is absent from the first active region 106. Then, the first gate dielectric layer and the gate electrode are sequentially deposited and collectively patterned by lithography process and etching to form the gate stack 114. In this case, the first dielectric layer is present on both the first and second active regions and the total thickness of the gate dielectric on the second active region 108 is the thickness of the first gate dielectric layer plus the thickness of the first gate dielectric layer. As different dielectric materials (such as high-k dielectric material) may be used in the gate dielectric, a thickness is evaluated relative to silicon oxide or equivalent oxide thickness. The first dielectric layer 116 and the second dielectric layer 118 may extend over to the isolation features 104 to eliminate the short issues. For example, the first dielectric layer 116 may extend to the second dielectric layer 118.

Gate spacer 122 may be further formed on the sidewalls of the gate electrode 120. The gate spacer 122 includes silicon oxide, silicon nitride, silicon oxynitride, other suitable dielectric material or a combination thereof. The gate spacer 122 may have a multilayer structure and may be formed by depositing dielectric material and then anisotropic etching, such as plasma etching.

The semiconductor structure 100 includes a channel 124 defined on the first active region 106 and underlying the gate stack 114. The channel 124 may be tuned for proper threshold voltage or other parameters by ion implantation. The channel 124 has a same type of dopant to that of the doped well 110 but a greater concentration, depending on the application and device specification. In the present example for nFET, the channel 124 is doped with a p-type dopant.

The semiconductor structure 100 includes a source 126 and a drain 128 formed on the first active region 106 on opposite sides of the gate stack 114. An N-type doped region 126 functions as a source and another N-type doped region 128 functions as a drain. The source 126 and drain 128 are doped with an N-type impurity such as phosphorous for an nFET. The source 126 and drain 128 may be formed by ion implantation and/or diffusion. Other processing steps may be further included to form the source and drain. For example, a rapid thermal annealing (RTA) process may be used to activate the implanted dopant. The source and drain may have different doping profiles formed by multi-step implantation. For example, additional doping features such as light doped drain (LDD) or double diffused drain (DDD) may be included. Also, the source and drain may have different structures, such as raised, recessed, or strained. For example, if the active regions are fin active regions, the formation of the source and drain may include an etching to recess the source and drain regions; epitaxial growth to form epitaxial source and drain with in-situ doping; and an annealing for activation. The channel 124 is interposed between the source 126 and the drain 128.

Particularly, the source 126 and the drain 128 are configured asymmetrically for some applications such as high voltage application. The drain 128, as a high voltage is applied during the field applications, is spaced away from the gate stack 114, thus the high voltage is able to be distributed in the region between the gate and the drain to reduce the high voltage damage to the device. The source 126 is configured close to the gate stack 114, such as an edge of the source is aligned to an edge of the gate stack 114, as illustrated in FIG. 1C. The formation of the source and drain may include forming a patterned mask to define the source and drain regions, and implantation or epitaxial growth to form the source and drain. For the similar reason as above, the drain 128 is free of silicide while the source 126 may further include a silicide layer 126A on the top surface to reduce the contact resistance. The drain 128 is free of silicide means there is no silicide in the drain, the contact(s) to the drain, and between the drain and the contact(s) to the drain. In one example, the silicide on the source may be formed by a self-aligned silicide procedure that further includes depositing a metal (such as nickel, cobalt, titanium or other suitable metal) on the source; performing an annealing process to react the metal with silicon of the source to form metal silicide; and etching to remove the unreacted metal.

In some embodiments, the source and drain are epitaxial source and drain. The epitaxial source and drain may be formed by selective epitaxial growth for straining effect with enhanced carrier mobility and device performance. The source and drain are formed by one or more epitaxial growth (epitaxial process), whereby silicon (Si) features, silicon germanium (SiGe) features, silicon carbide (SiC) features, and/or other suitable semiconductor features are grown in a crystalline state on the first active region within the source and drain regions (such as defined by a patterned hard mask). In an alternative embodiment, an etching process is applied to recess portions of the first active region 106 within the source and drain regions before the epitaxy growth. The etching process may also remove any dielectric material disposed on the source/drain regions, such as during the formation of the gate sidewall features. Suitable epitaxy processes include CVD deposition techniques (e.g., vapor-phase epitaxy (VPE) and/or ultra-high vacuum CVD (UHV-CVD), molecular beam epitaxy, and/or other suitable processes. The source 126 and the drain 128 may be in-situ doped during the epitaxy process by introducing doping species including: n-type dopants, such as phosphorus or arsenic (or p-type dopants, such as boron or BF₂ for pFET). If the source and drain are not in-situ doped, an implantation process (i.e., a junction implant process) is performed to introduce the corresponding dopant into the source and drain. In some other embodiments, the raised source and drain are formed by epitaxial growth with more than one semiconductor material layers. For example, a silicon germanium layer is epitatially grown on the substrate within the source and drain regions and a silicon layer is epitaxially grown on the silicon germanium layer.

The semiconductor structure 100 further includes contact features, such as 130A, 130B and 130C, formed on various doped regions. As an example illustrated in FIG. 1A, two contact features 130A are formed on the source 126; two contact features 130B are formed on the drain 128; and two contact features 130C are formed on the doped feature 112, such as one on each side of the gate stack 114. In the present embodiment, the silicide may be formed between the contact features (such as 130A and 130C) and the corresponding doped features (such as the source 126 and the doped feature 112) while being absent from the interface between the drain 128 and the contact features 130B, as noted above. The gate stack 114 is free of any contact feature (there is no contact feature directly landing on the gate electrode 120) since the contact features 130C function as gate contact.

Thus formed semiconductor structure 100 functions as a FET 132 (or an nFET in the present example) with dual gate dielectric layers 116 and 118 configured on different active regions 106 and 108, respectively. Particularly, the source 126, drain 128, the gate stack 114 and other components (such as the channel 124) are configured into an nFET. The doped feature 112 and the contact feature(s) 130C collectively function as the gate contact, which is further connected to a signal line for gate signal. There is no any contact feature directly landing on the gate electrode 120.

This structure of the FET 132 achieves high-voltage performance and overcomes the noise/charging issues discussed before. Usually, a FET requires its gate dielectric layer to be thicker to have a better high-voltage performance and be thinner to overcome the noise/charging issues. A conventional FET structure cannot satisfy the both. The disclosed FET 132 has a first gate dielectric layer 116 directly disposed on the channel 124 and a second gate dielectric layer 118 not disposed on the channel 124. The high-voltage performance is determined by both the first gate dielectric layer 116 and the second gate dielectric layer 118 while the noise/charging issue is associated only with the gate dielectric layer 116 directly disposed on the channel. Thus, the two gate dielectric layers can be separately tuned to satisfy both needs. This is further explained below.

For the noise/charging issue, the electrical current in the channel 124 from the carrier (electrons in nFET or holes in pFET) cannot avoid being trapped and de-trapped by the first gate dielectric layer 116 directly on the channel 124, thereby generating noises, such as random telegraph signal (RTS) and flicker noise. The charging (trapping and de-trapping) effect can be reduced by thinning down the thickness of the first gate dielectric layer 116.

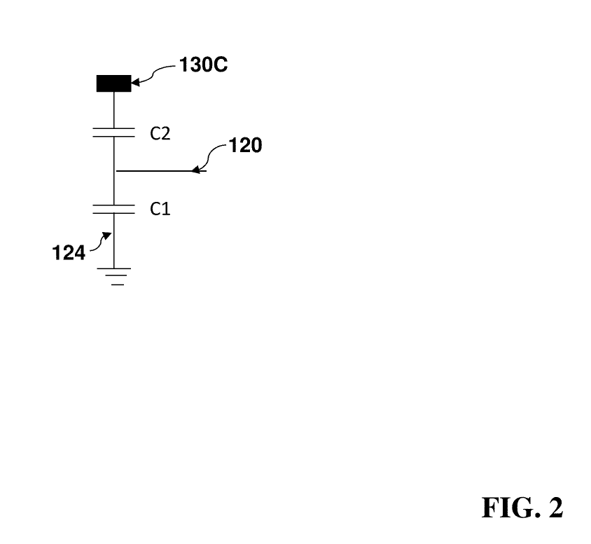

When a voltage is applied to the contact feature(s) 130C, it is coupled to the gate electrode 120 through the second gate dielectric layer 118 and further coupled to the channel 124 through the first gate dielectric layer 116. Thus, the gate electric bias is coupled to the channel 124 through two capacitors in series: the first capacitor C1 associated with the first gate dielectric layer 116 and the second capacitor C2 associated with the second gate dielectric layer 118, as illustrated in FIG. 2 in a schematic view. If the equivalent oxide thickness of the first gate dielectric layer 116 is T1 and the equivalent oxide thickness of the second gate dielectric layer 118 is T2, the total equivalent oxide thickness of the collective gate dielectric layer is T=T1+T2. As an example for illustration, assume that T2=4*T1, and a voltage V=3.63V is applied to the gate contact 130C. In furtherance of the example, T1 is about 10 nm and T2 is about 40 nm. The voltage to the gate electrode 120 is Vg=V*T1/(T1+T2)=V/5. Accordingly, the voltage V is distributed to the dual gate dielectric layers and the voltage to the gate electrode 120 is substantially reduced. Thus, the transistor 132 has robust high voltage strength since a large share of the voltage V is dropped on the second gate dielectric layer 118. The transistor 132 can be viewed from different perspective. The doped feature 112, as it is configured, functions as the gate electrode, and it couples to the channel 124 through the first gate dielectric layer 116 and the second gate dielectric layer 118 with equivalent oxide thickness T=T1+T2. By decreasing the thickness of the first gate dielectric layer 116 and increasing the thickness of the second gate dielectric layer 118, both the charging effect is reduced and the high-voltage performance is achieved.

Furthermore, there is additional benefit from the disclosed structure. Because there is no connect features directly formed on the gate electrode, there is no antenna effect in the subsequent plasma processes (such as ion implantation, plasma etching, and plasma deposition). The plasma induced damages to the transistor during the fabrication are also substantially reduced due or eliminated. The dual dielectric transistor 132 has a thicker gate dielectric which benefits for improved high-voltage performance and also has a thin gate dielectric which benefits to reduce/eliminate charging effect, and reduce plasma-induced damage.

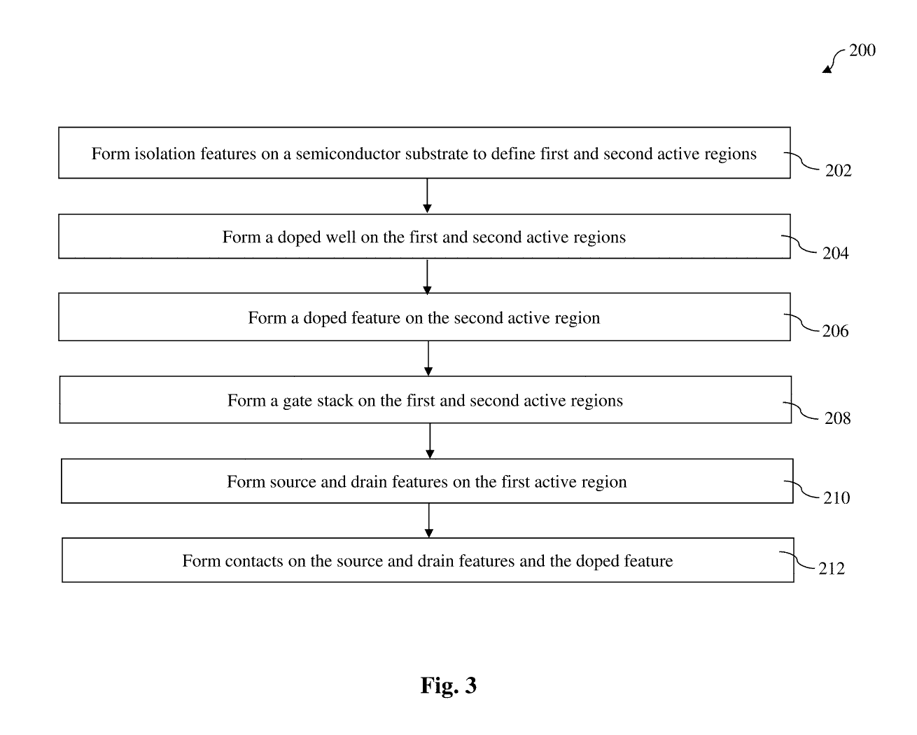

FIG. 3 is a flowchart of the method 200 for making the semiconductor structure 100 having a dual gate dielectric FET. FIGS. 3A, 4A, 5A, 6A and 7A are top views of the semiconductor structure 100 at various fabrication stages. FIGS. 3B, 4B, 5B, 6B and 7B are sectional views of the semiconductor structure 100 along dashed line AA′ at various fabrication stages. FIGS. 3C, 4C, 5C, 6C and 7C are sectional views of the semiconductor structure 100 along dashed line BB′ at various fabrication stages. FIGS. 3D, 4D, 5D, 6D and 7D are sectional views of the semiconductor structure 100 along dashed line CC′ at various fabrication stages. The method 200 is described with reference to FIGS. 3A-7D and other figures. As some detailed description is provided with FIGS. 1A-1D, those languages will not be repeated here.

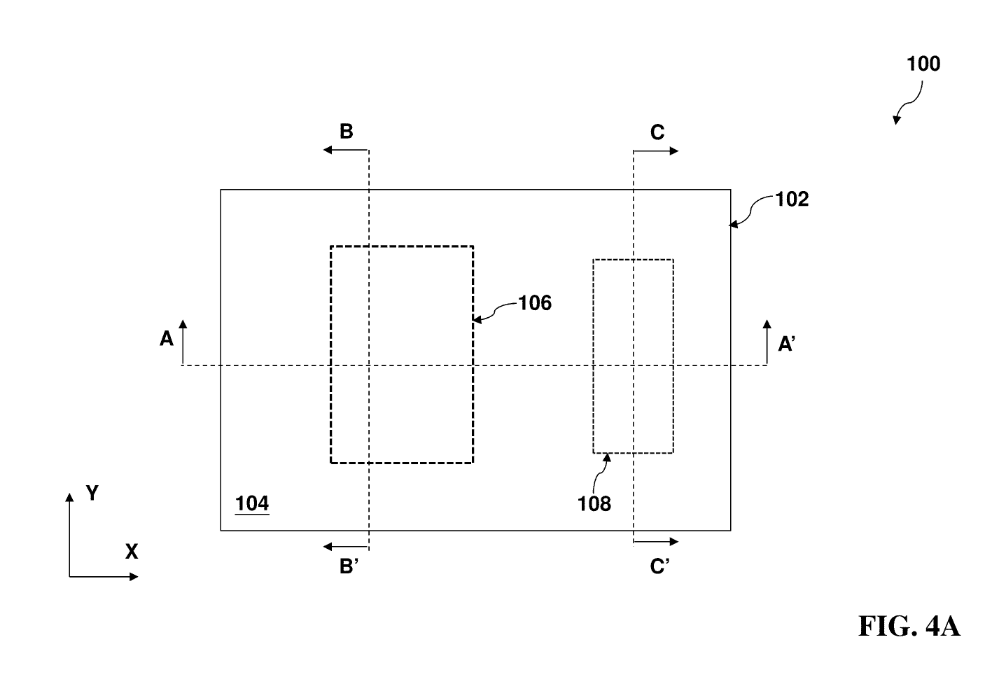

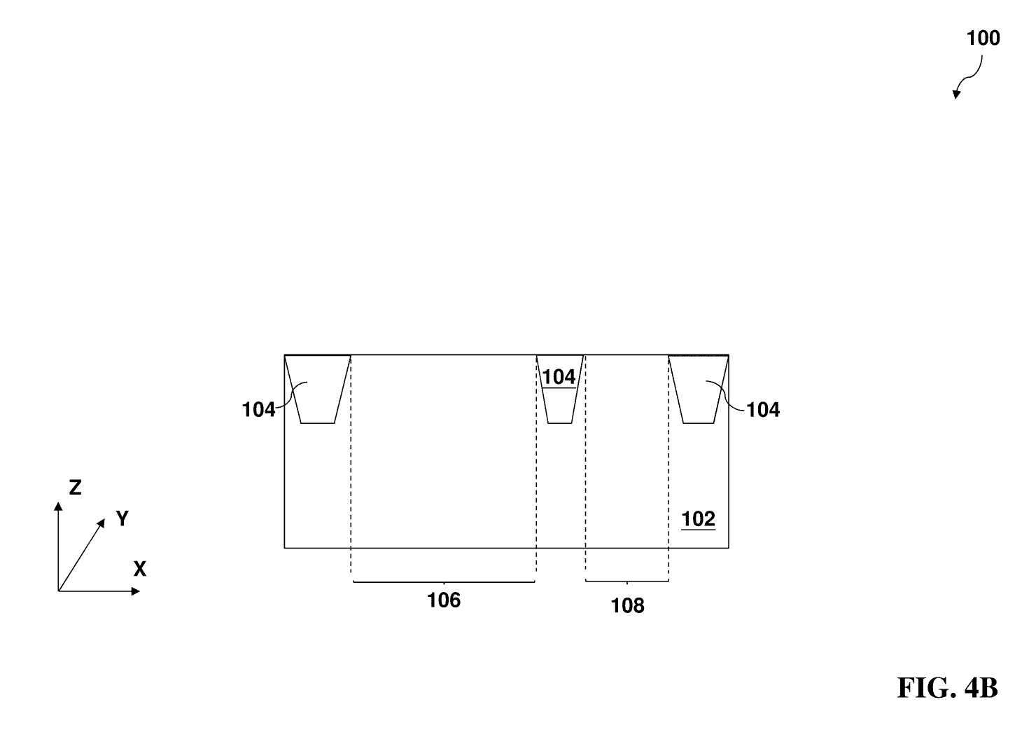

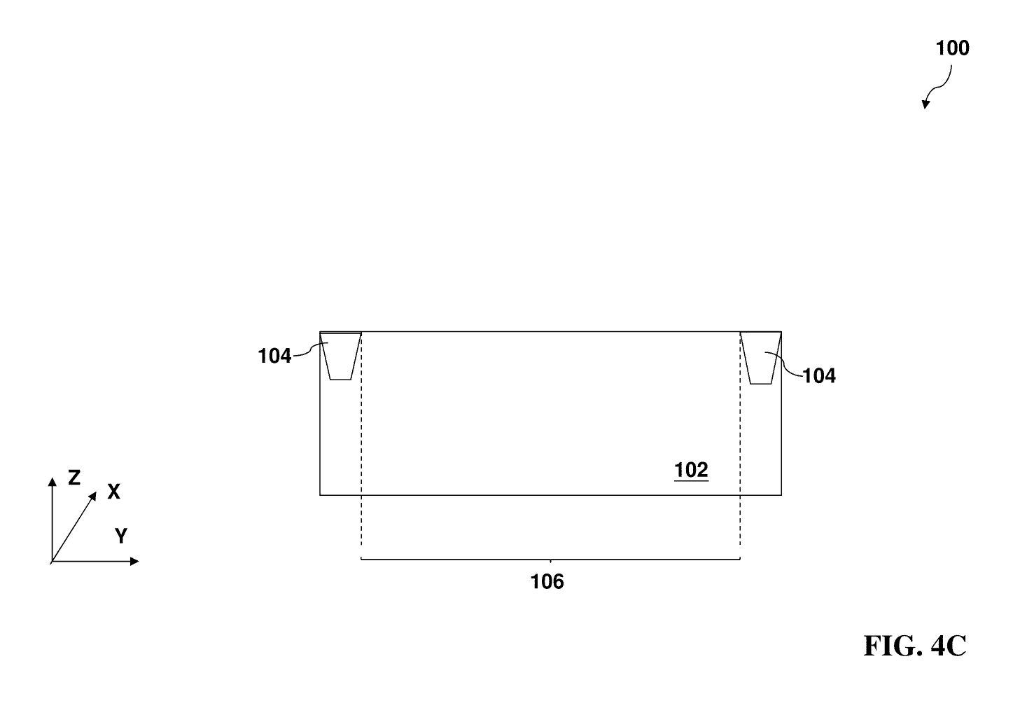

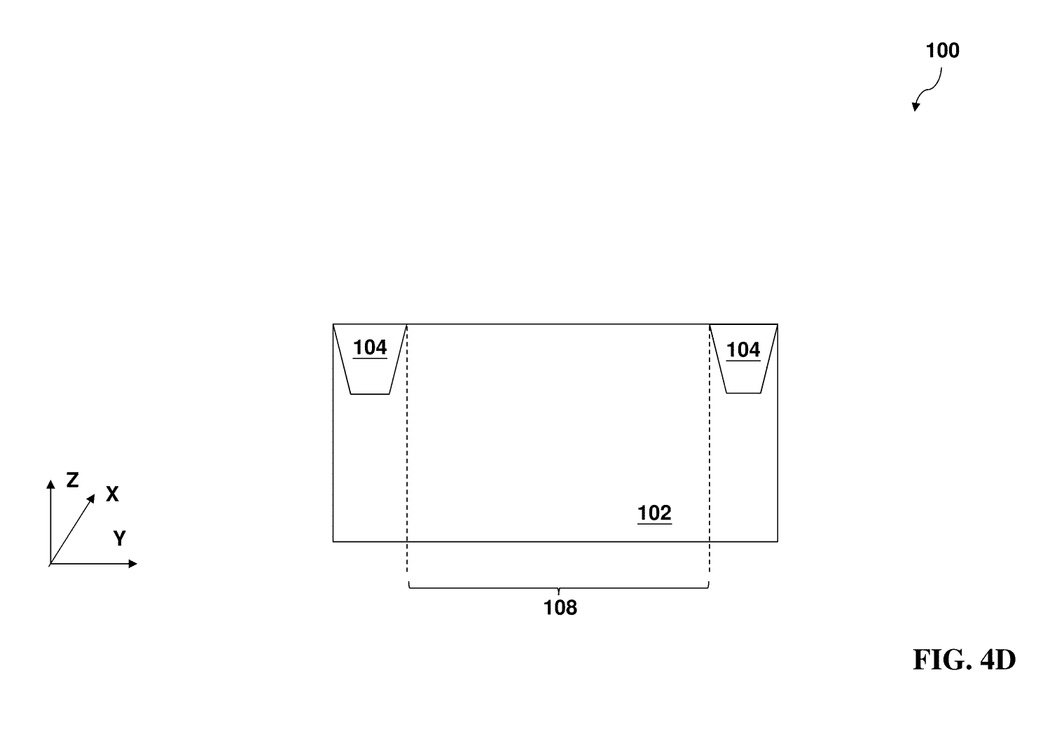

Referring to block 202 of FIG. 3 and FIGS. 4A-4D, the method 200 includes an operation to form isolation features 104 in the semiconductor substrate 102, thereby defining a first active region 106 and a second active region 108 separated from each other by the isolation feature 104. The formation of the isolation features may include forming a patterned mask by lithography; etching the substrate 102 through the openings of the patterned mask to form trenches; filling the trench with one or more dielectric material; and performing a CMP process. In some embodiments, the active regions may be three-dimensional, such as fin active regions. In this case, the operation 202 may further includes selective etching to recess the isolation features 104 or selective epitaxial growth to the active regions with one or more semiconductor material.

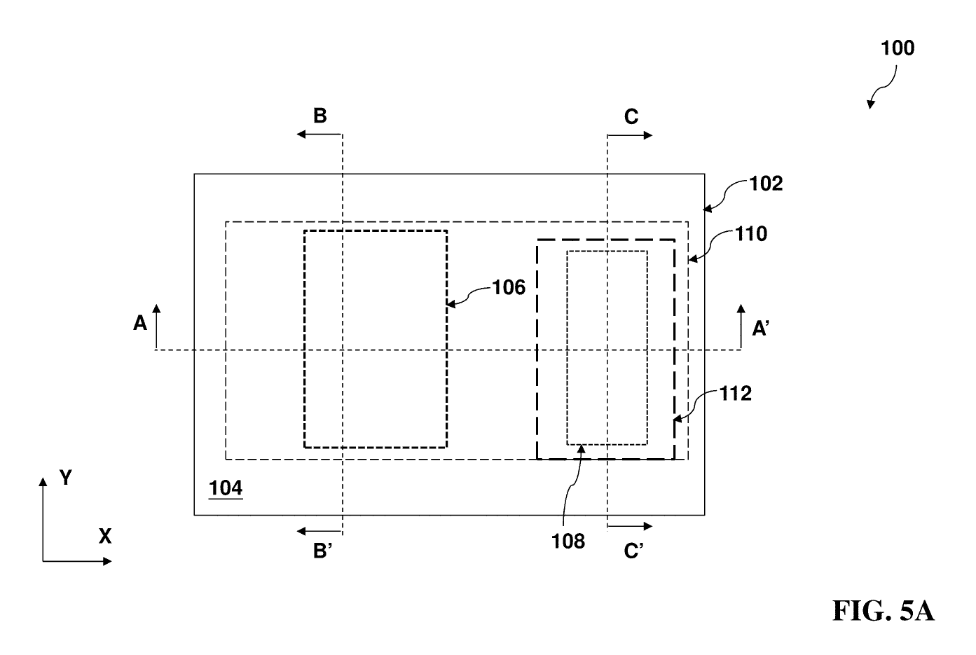

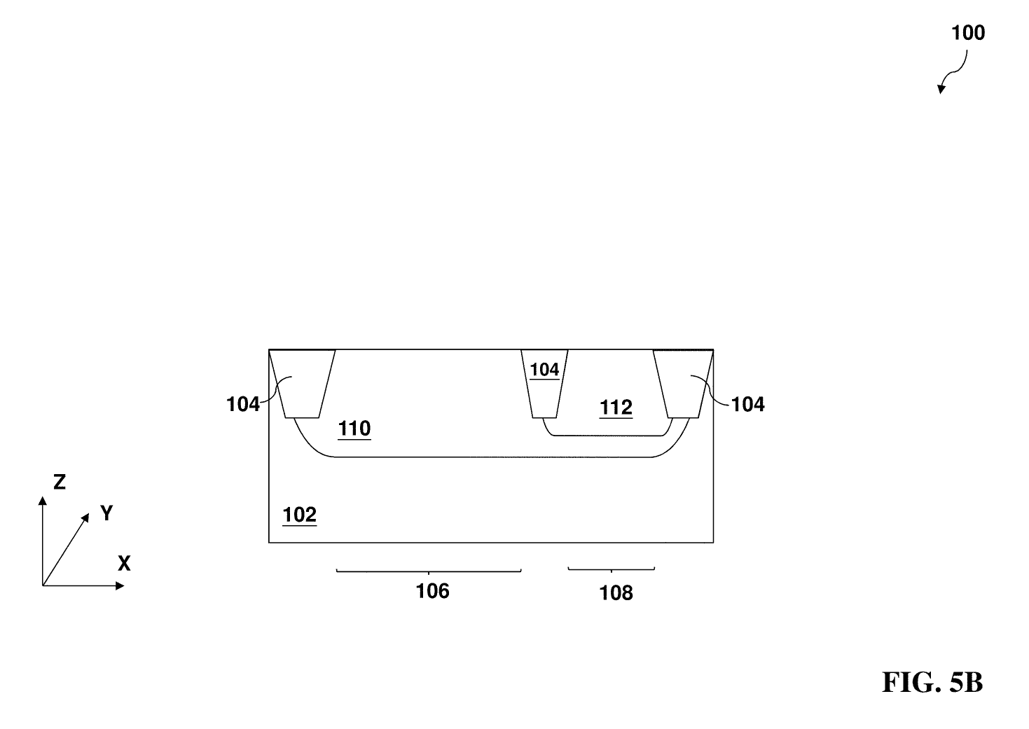

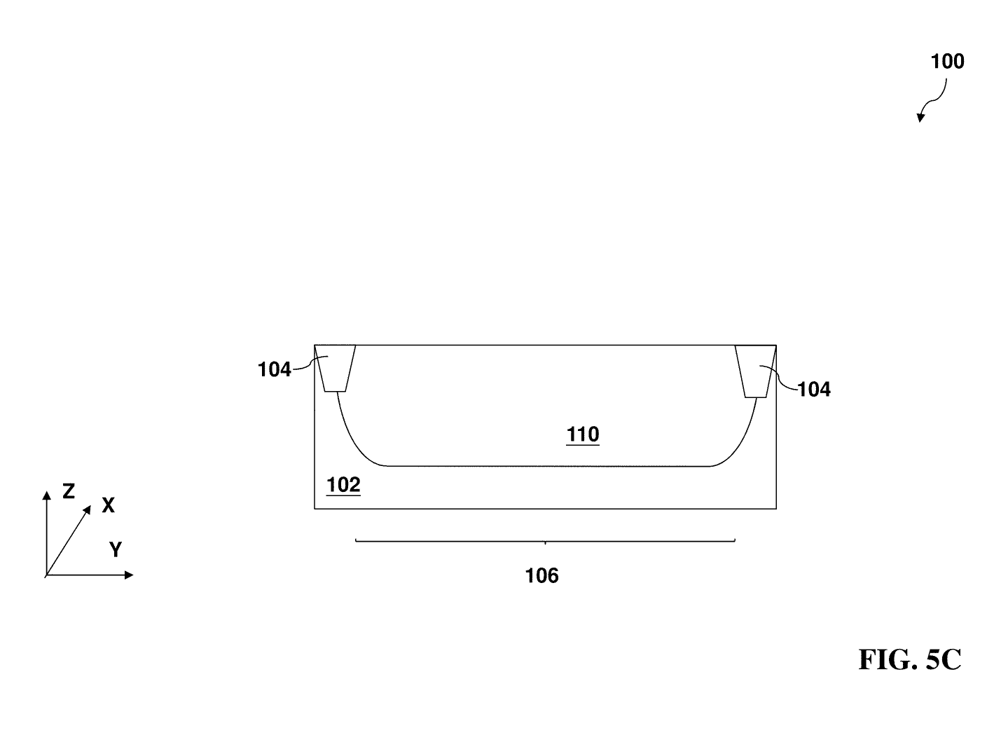

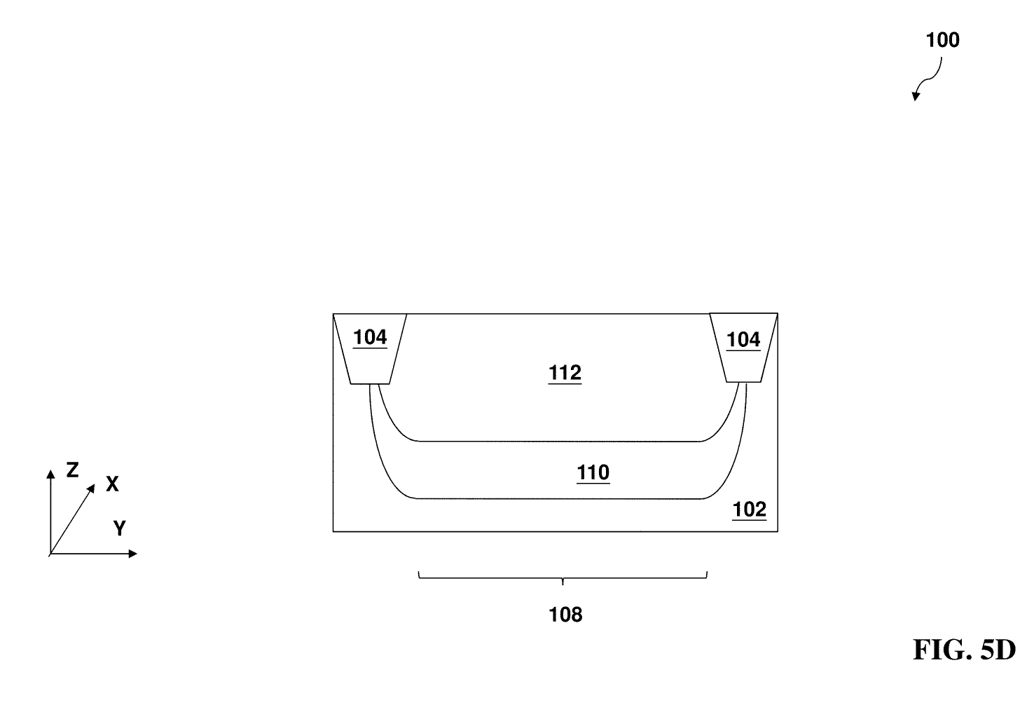

Referring to block 204 of FIG. 3 and FIGS. 5A-5D, the method 200 includes an operation to form a doped well 110 on both the first active region 106 and the second active region 108. The doped well 110 extends along the X direction from the first active region 106 to the second active region 108 such that the first and second active regions are enclosed within the doped well 110 along the X direction, as illustrated in FIG. 5B. In the present embodiment, the doped well 110 fully encloses the first and second active regions along both X and Y directions as illustrated in FIG. 5A. The doped well 110 is formed by ion implantation or other suitable technique.

Referring to block 206 of FIG. 3 and FIGS. 5A-5D, the method 200 includes an operation to form a doped feature 112 on the second active region 108 by a suitable technique, such as ion implantation. The doped feature 112 is enclosed in the doped well 110 as illustrated in FIG. 5B. The doped feature 112 extends on the second active region 108 from one region on one side of the gate stack 114 to another region on opposite side of the gate stack 114. The doped feature 112 is doped with a same type of dopant, such as n-type or p-type. The doped feature 112 is heavily doped for reduced resistance and improved conductivity to function as contact to the gate stack 114 with its configuration.

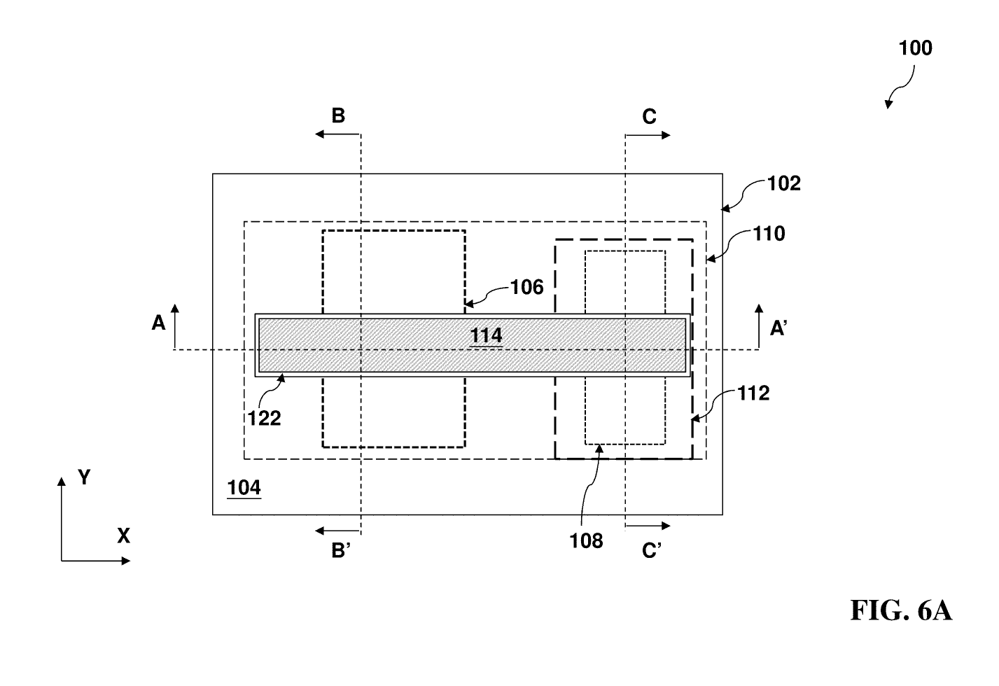

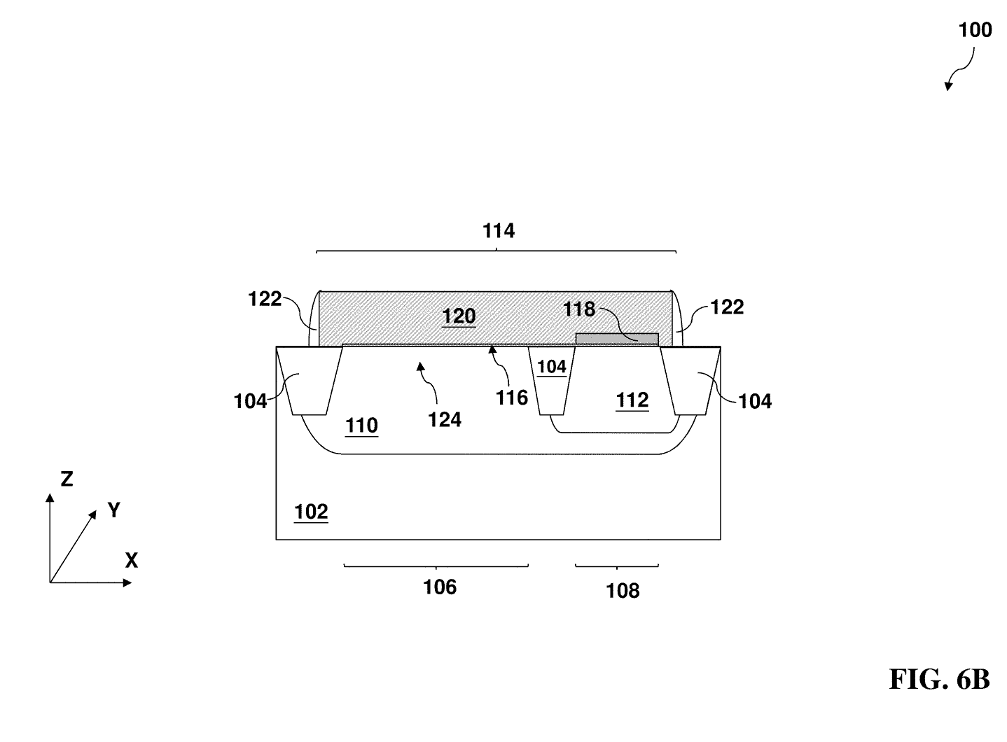

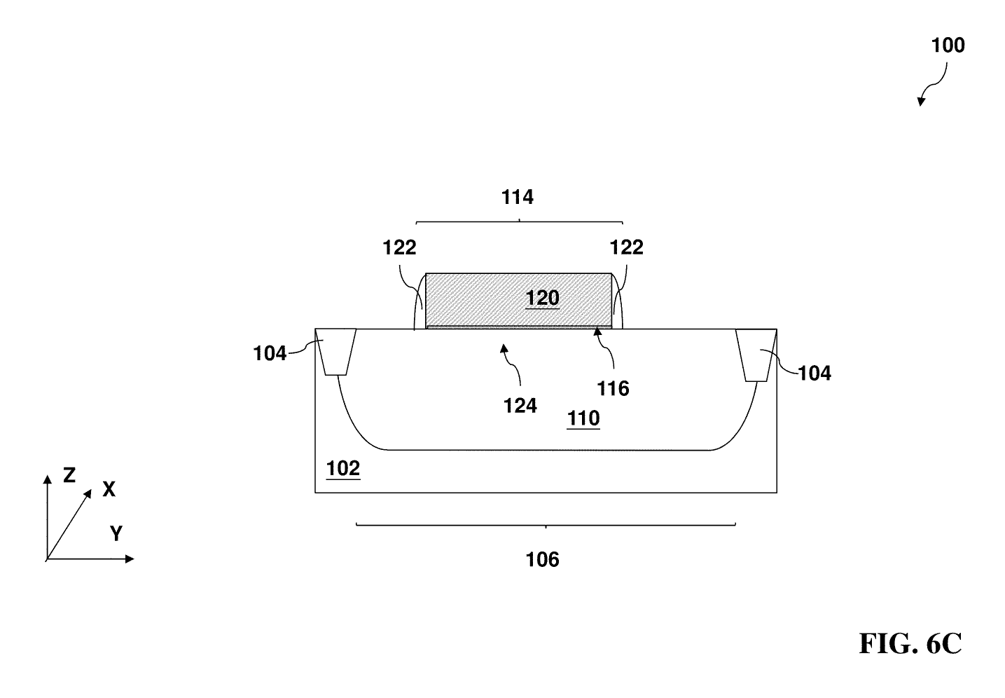

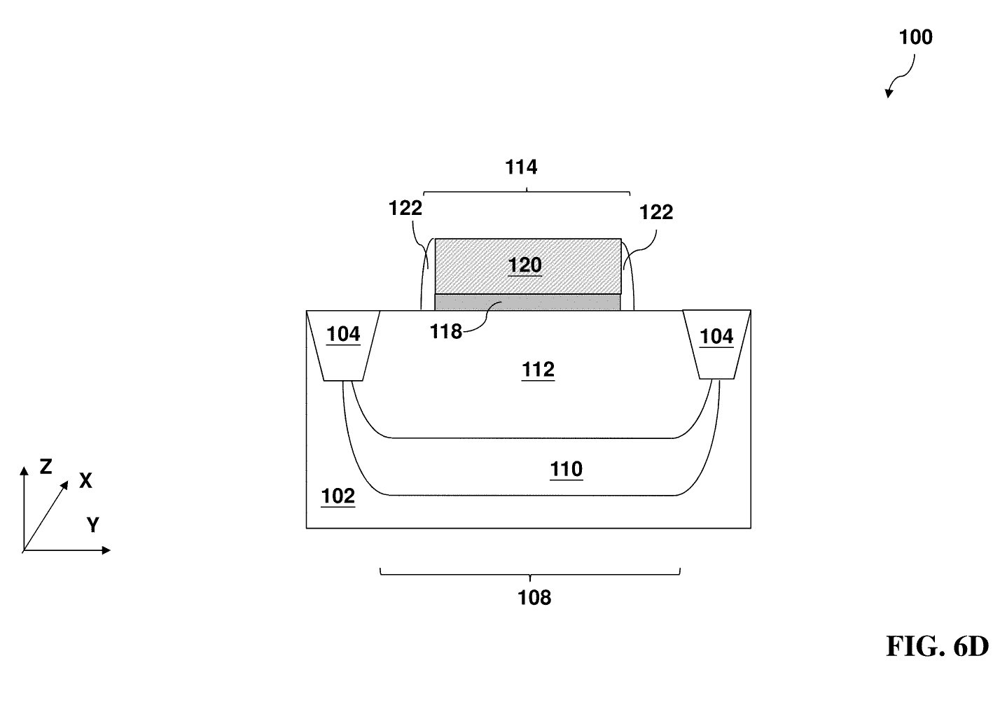

Referring to block 208 of FIG. 3 and FIGS. 6A-6D, the method 200 includes an operation to form a gate stack 114 on the substrate 102. The gate stack 114 includes a first gate dielectric layer 116 of a first equivalent oxide thickness T1 on the first active region 106 and a second gate dielectric layer 118 of a second equivalent oxide thickness T2 on the second active region 108. The second thickness T2 is greater than the first thickness T1. The gate dielectric layers may include silicon oxide, high-k dielectric material, other suitable dielectric material, or a combination thereof. The gate stack also includes gate electrode 120 extended from the first gate dielectric layer 116 on the first active region 106 to the second gate dielectric layer 118 on the second active region 108. The gate electrode 120 includes any suitable conductive material, such as doped poly-silicon, metal, metal alloy, or metal silicide. The gate stack 114 may also include gate spacer 122 formed on sidewalls of the gate electrode 120. The gate spacer 122 includes one or more dielectric material, such as silicon oxide or silicon nitride. The formation of the gate stack 114 may include a gate-last process, a high-k-last process, or other suitable procedure.

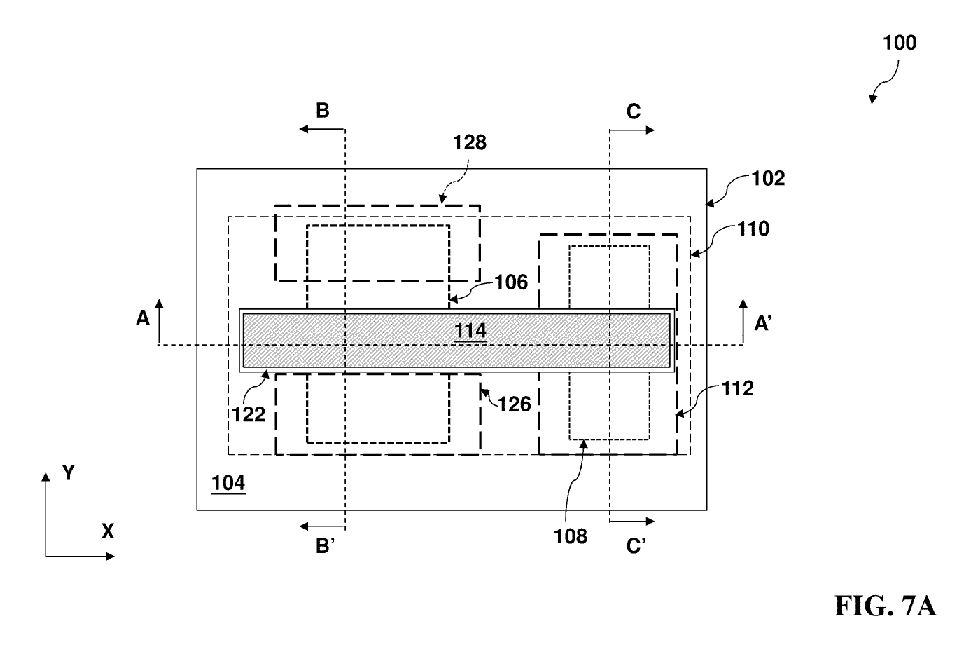

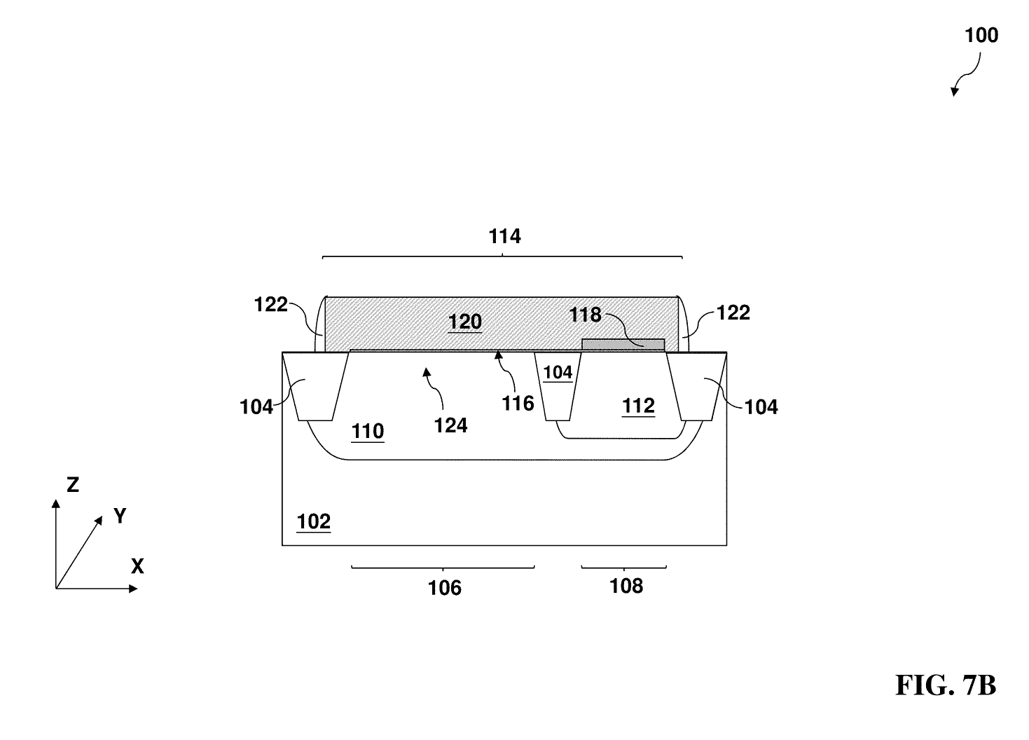

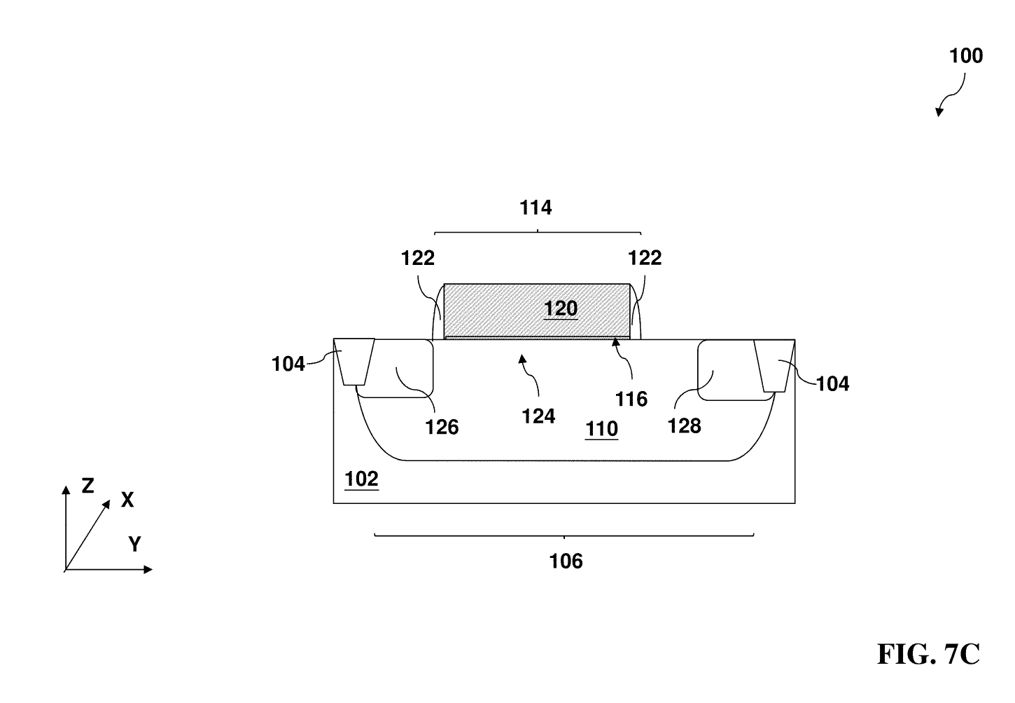

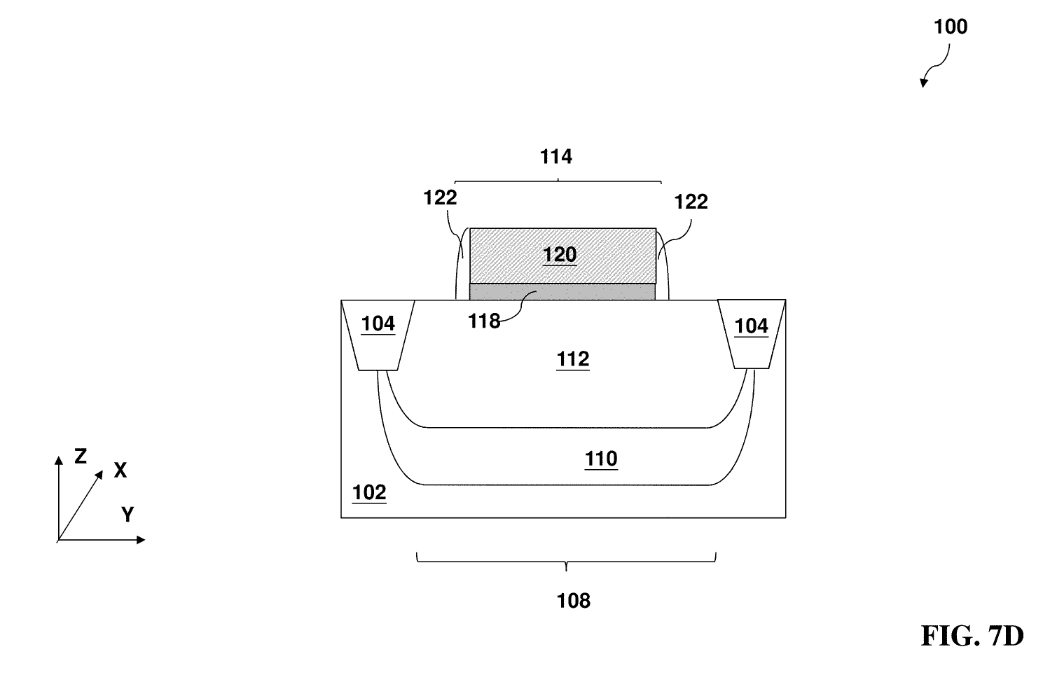

Referring to block 210 of FIG. 3 and FIGS. 4A-4D, the method 200 includes an operation to form source 126 and drain 128 on the first active region 106, wherein the source 126 and the drain 128 are interposed by the channel 124 underlying the gate stack 114. Particularly, the source 126 and the drain 128 are asymmetrically configured on opposite sides of the gate stack 114. The drain 128 is spaced away from the gate stack 114 while the source 126 is aligned to the edge of the gate stack, as illustrated in FIG. 7C.

Referring to block 212 of FIG. 3 and FIGS. 1A-1D, the method 200 includes an operation to form contact (also referred to as contact features), such as contact features 130A to the source 126, contact features 130B to the drain 128; and contact features 130C to the doped feature 112. It is noted that there is not contact feature directly on the gate electrode 120 since the contact features 130C and the doped feature 112 are configured to collectively function as the gate contact. Especially, the contact features 130B are free of silicide while other contact features (130A and 130C) may further include silicide.

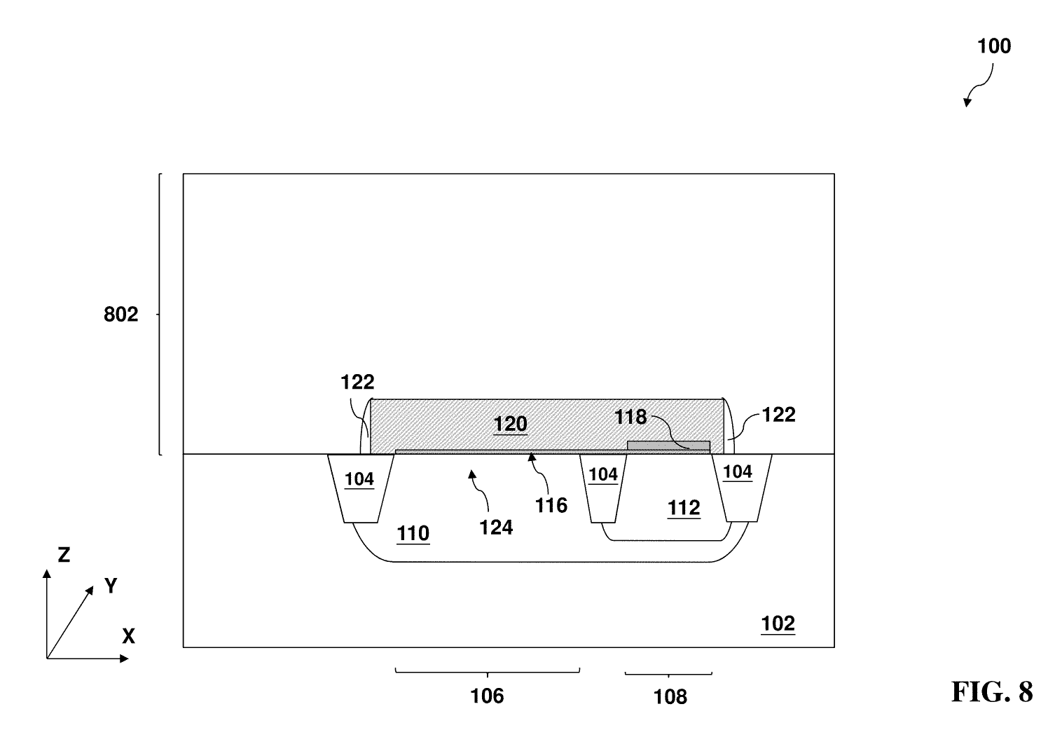

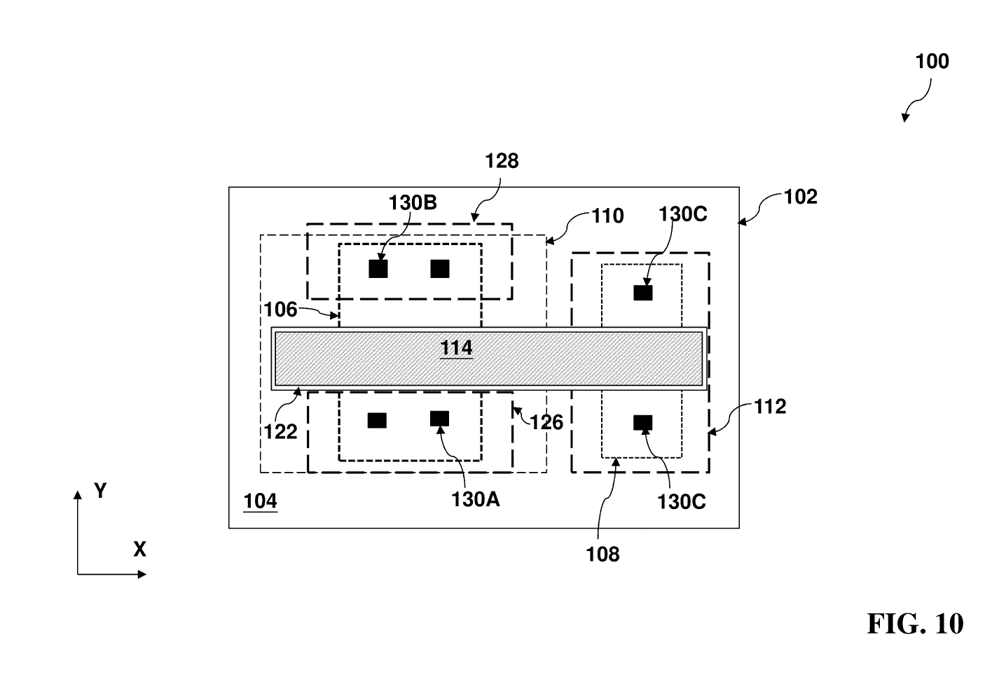

The method 200 may additionally include other operations before, during or after the operations described above. For example, the method 200 may include an operation to form an interconnection structure 802 to couple various features into a FET and further couple various devices into an integrated circuit, as illustrated in FIG. 8 in a sectional view. Particularly, the contact features 130C are connected to a line for gate signal. The interconnection structure 802 includes multiple metal layers with metal lines for horizontal connection and further includes via features for vertical connection between adjacent meal layers. The interconnection structure 802 further dielectric material(s), such interlayer dielectric (ILD) to provide isolation functions to various conductive features embedded therein. In the present example for illustration. The interconnection structure 802 includes contacts (such as 130A, 130B and 130C in FIG. 10); metal lines in metal one layer over the contacts; metal lines in metal two layer over the metal one layer; metal lines in metal three layer over the metal two layer; via features between the metal one layer and the metal two layer; via features between the metal two layer and the metal three layer; and so on. The interconnection structure 802 may be formed by a suitable technology, such as single damascene process, dual damascene process or other suitable process. Various conductive features (contact features, via features and metal lines) may include copper, aluminum, tungsten, silicide, other suitable conductive material or combinations thereof. The ILD may include silicon oxide, low-k dielectric material, other suitable dielectric material or a combination thereof. The ILD may include multiple layers, each further including an etch stop layer (such silicon nitride) to provide etch selectivity. Various conductive features may further include lining layers, such as titanium nitride and titanium, to provide barrier to prevent inter-diffusion, adhesion or other material integration effects.

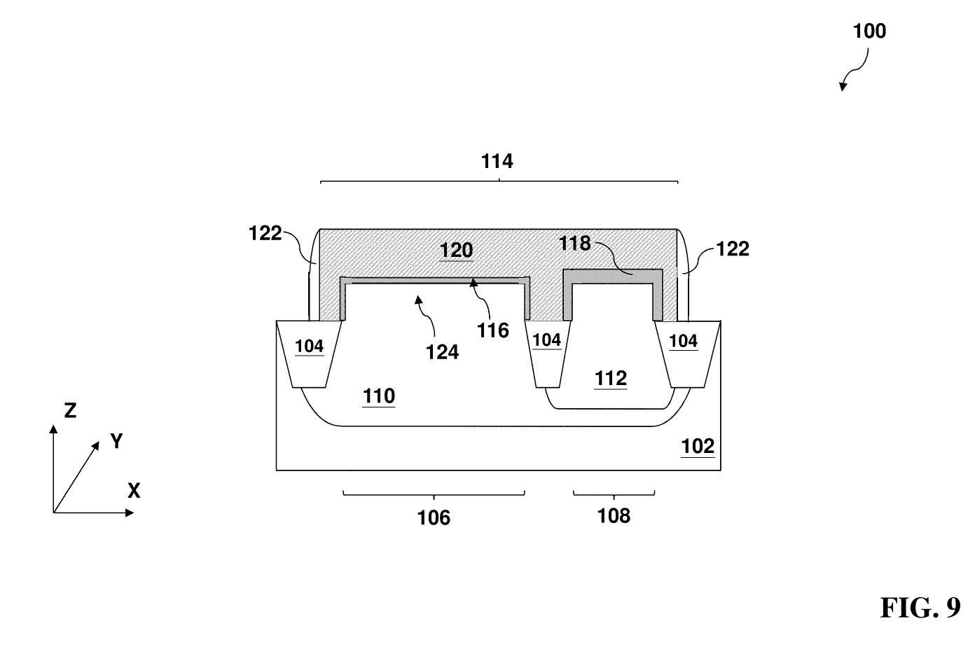

In other example, after the formation of the isolation features 104 by the operation 202, the method 200 may further include an operation to form fin active regions 106 and 108 by selective etching to the isolation features 104, selective epitaxial growth to the active regions, a combination thereof. Thus formed active regions, such as 106 and 108, are extruded above the isolation features 104 as illustrated in FIG. 9 in a sectional view, therefore providing a three-dimensional structure with enhanced device performance since the gate electrode 120 is disposed on the top surface and side surfaces of the fin active regions.

Even though only one dual gate dielectric FET (an nFET) is described in the semiconductor structure 100 and the method 200 making the same, it is understood that other embodiments or alternative may present without departure from the scope of the present disclosure. For example, the dual gate dielectric FET can be an n-type or a p-type (pFET) or a complimentary with a pair of nFET and pFET integrated together. If it is a p-type, the all above dopant types for an nFET are reversed. For example, the source 126 and the drain 128 are p-type doped, and the doped well 110 and the channel 124 are n-type doped. In some alternative embodiments, the doped well 110 may be formed only on the first active region 106 and the doped feature 112 is formed on the second active region 108. In this case, both the doped feature 112 and the second active region 108 are configured outside of the doped well 110 in a top view, as illustrated in FIG. 10.

The present disclosure provides a field-effect transistor having dual gate dielectric layers and gate contact on an active region in accordance with various embodiments. There is no contact feature directly on the gate electrode. Various advantages may present in various embodiments. By utilizing the disclosed dual dielectric FET (DDFET) structure, the transistor maintains thicker gate dielectric advantages with dual gate dielectric layer for improved high voltage performance and maintains thin gate dielectric advantages including: reduced or eliminated RTS and flicker noise, and reduced plasma induced damage. The dual dielectric FET may be formed as an nFET, pFET, a complimentary FET (having paired nFET and pFET), or other suitable structure. The dual dielectric transistor can be used for I/O device, high voltage applications, radio-frequency (RF) applications, analog circuits and other generic applications with substantially reduced noises and maintained high voltage performance. Especially, the disclosed structure and method are compatible with advanced technologies with smaller feature sizes, such as the advanced technology of 7 nm.

Thus, the present disclosure provides a semiconductor structure in accordance with some embodiments. The semiconductor structure includes a semiconductor substrate; a first active region and a second active region on the semiconductor substrate and separated by an isolation feature; and a field-effect transistor formed on the semiconductor substrate. The field-effect transistor further includes a gate stack disposed on the semiconductor substrate and extending from the first active region to the second active region; a source and a drain formed on the first active region and interposed by the gate stack; and a doped feature formed on the second active region and configured as a gate contact to the field-effect transistor.

The present disclosure also provides a semiconductor structure in accordance with some embodiments. The semiconductor structure includes a semiconductor substrate; a first active region and a second active region on the semiconductor substrate, wherein the first active region and the second active region are laterally separated by an isolation feature; a gate stack disposed on the semiconductor substrate and extending from the first active region to the second active region; a source and a drain formed on the first active region and interposed by the gate stack; and a doped feature formed on the second active region and extending from a first region underlying the gate stack to a second region laterally beyond the gate stack. The source, the drain and the gate stack are configured as a field-effect transistor and the doped feature is configured as a gate contact to the gate stack of the field-effect transistor.

The present disclosure provides a semiconductor structure in accordance with some embodiments. The semiconductor structure includes a semiconductor substrate; a first active region and a second active region on the semiconductor substrate, wherein the first active region and the second active region are laterally separated by an isolation feature; a gate stack disposed on the semiconductor substrate and extending from the first active region to the second active region; a channel formed on the first active region and underlying the gate stack; a source and a drain formed on the first active region and interposed by the channel; and a doped feature formed on the second active region and extending from a first region underlying the gate stack to a second region laterally beyond the gate stack. The source, the drain, channel and the gate stack are configured as a field-effect transistor and the doped feature is configured as a gate contact to the gate stack of the field-effect transistor.

The present disclosure provides a method in accordance with some embodiments. The method includes forming an isolation feature, a first active region and a second active region on a semiconductor substrate, wherein the first active region and the second active region are laterally separated by the isolation feature; forming a gate stack on the semiconductor substrate, the gate stack extending from the first active region to the second active region; forming a source and a drain on the first active region and interposed by a channel that is on the first active region and underlying the gate stack; and forming a doped feature on the second active region, the doped feature extending from a first region underlying the gate stack to a second region laterally beyond the gate stack. The source, the drain, channel and the gate stack are configured as a field-effect transistor and the doped feature is configured as a gate contact to the gate stack of the field-effect transistor.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A semiconductor structure, comprising:
a semiconductor substrate;
a first active region and a second active region on the semiconductor substrate and separated by an isolation feature;
a field-effect transistor formed on the semiconductor substrate, wherein the field-effect transistor includes
a gate stack disposed on the semiconductor substrate and extending from the first active region to the second active region; and
a source and a drain formed on the first active region and interposed by the gate stack; and
a doped feature formed on the second active region and configured as a gate contact to the field-effect transistor.

2. The semiconductor structure of claim 1, wherein the doped feature extends on the second active region from a first region on a first side of the gate stack to a second region on a second side of the gate stack, the second side being opposite to the first side.

3. The semiconductor structure of claim 2, wherein the gate stack includes a first gate dielectric layer on the first active region and a second gate dielectric layer on the second active region, wherein the first gate dielectric layer has a first thickness and the second gate dielectric layer has a second thickness being greater than the first thickness.

4. The semiconductor structure of claim 3, wherein the gate stack further includes a gate electrode disposed on the first and second gate dielectric layers, wherein the gate electrode is a conductive feature and continuously extends from the first gate dielectric layer on the first active region to the second gate dielectric layer on the second active region, and wherein there is no conductive feature directly landing on the gate electrode.

5. The semiconductor structure of claim 2, wherein the doped feature is heavily doped with a first type dopant.

6. The semiconductor structure of claim 5, further comprising a doped well doped with a second type dopant being opposite to the first type dopant, wherein the doped well extends from the first active region to the second active region, and wherein the doped well encloses the doped feature.

7. The semiconductor structure of claim 6, wherein the source and drain are heavily doped with the first type dopant.

8. The semiconductor structure of claim 2, wherein the field-effect transistor has an asymmetric structure with the drain being spaced a distance from the gate stack on the first side and the source being configured at an edge of the gate stack on the second side.

9. The semiconductor structure of claim 8, further comprising a silicide layer formed on the source, wherein the drain is free of silicide.

10. The semiconductor structure of claim 9, further comprising:
a first conductive feature formed on the silicide layer and configured as a contact feature to the source; and
a second conductive feature formed on the drain and configured as a contact feature to the drain.

11. The semiconductor structure of claim 2, further comprising conductive features landing on the doped feature within the first region and the second region, wherein the conductive features are connected to a signal line for a signal to the gate electrode.

12. The semiconductor structure of claim 1, wherein the first and second active regions are fin active regions extruded above the isolation feature.

13. A semiconductor structure, comprising:
a semiconductor substrate;
a first active region and a second active region on the semiconductor substrate, wherein the first active region and the second active region are laterally separated by an isolation feature;
a gate stack disposed on the semiconductor substrate and extending from the first active region to the second active region;
a source and a drain formed on the first active region and interposed by the gate stack; and
a doped feature formed on the second active region and extending from a first region underlying the gate stack to a second region laterally beyond the gate stack,
wherein the source, the drain and the gate stack are configured as a field-effect transistor and the doped feature is configured as a gate contact to the gate stack of the field-effect transistor.

14. The semiconductor structure of claim 13, further comprising
a first conductive feature landing on the doped feature within the second region and connected to a signal line for a signal to the gate stack;
a second conductive feature formed on the source and configured as a contact feature to the source; and
a third conductive feature formed on the drain and configured as a contact feature to the drain.

15. The semiconductor structure of claim 13, further comprising a doped well doped with a first type dopant, wherein the doped well laterally encloses the first active region, the second active region, and the doped feature, wherein the doped feature is heavily doped with a second type dopant being opposite to the first type dopant.

16. The semiconductor structure of claim 15, wherein the field-effect transistor has an asymmetric structure with the drain being spaced a distance from the gate stack on a first side of the gate stack and the source being configured at an edge of the gate stack on a second side of the gate stack, the second side being opposite to the first side.

17. The semiconductor structure of claim 15, further comprising a silicide layer interposed between the source and the second conductive feature, wherein the third conductive feature is directly landing on the drain without silicide between the third conductive feature and the drain.

18. The semiconductor structure of claim 13, wherein the gate stack includes a first gate dielectric layer on the first active region and a second gate dielectric layer on the second active region, wherein the first gate dielectric layer has a first thickness and the second gate dielectric layer has a second thickness being greater than the first thickness.

19. The semiconductor structure of claim 18, wherein the gate stack further includes a gate electrode disposed on the first and second gate dielectric layers, wherein the gate electrode is a conductive feature and continuously extends from the first gate dielectric layer on the first active region to the second gate dielectric layer on the second active region.

20. A method, comprising:
forming an isolation feature, a first active region and a second active region on a semiconductor substrate, wherein the first active region and the second active region are laterally separated by the isolation feature;
forming a gate stack on the semiconductor substrate, the gate stack extending from the first active region to the second active region;
forming a source and a drain on the first active region and interposed by a channel that is on the first active region and underlying the gate stack; and
forming a doped feature on the second active region, the doped feature extending from a first region underlying the gate stack to a second region laterally beyond the gate stack,
wherein the source, the drain, the channel and the gate stack are configured as a field-effect transistor and the doped feature is configured as a gate contact to the gate stack of the field-effect transistor.
